(19) United States
(12) Patent Application Publication
(10) Pub. No.: US 2008/0156635 A1
(43) Pub. Date: Jul. 3, 2008

(54) SYSTEM FOR PROCESSES INCLUDING FLUORINATION

(76) Inventor: Bogdan M. Simon, Chandler, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/618,907

(22) Filed: Dec. 31, 2006

(51) Int. Cl. C23C 14/00

(52) U.S. Cl. 204/192.1; 204/298.07

(57) ABSTRACT

Certain embodiments relate to treating bodies such as indium preforms on a tape, using a processing system. In one embodiment, the system is adapted to receive and process a tape, and includes a gas mixing chamber adapted to receive a plurality of gases. The system also includes a processing chamber adapted to receive gas from the gas mixing chamber and adapted to receive a tape to be processed using the gas. The system also includes a gate valve positioned between the gas mixing chamber and the processing chamber. The system also includes an inlet chamber adapted to transmit an unprocessed tape into the processing chamber, and an outlet chamber adapted to receive a processed tape from the processing chamber. The system also includes a first conduit in communication with the inlet chamber and configured to form a loop with the inlet chamber, the first conduit adapted to transmit a gas flow around the loop and through the inlet chamber, and a second conduit in communication with the outlet chamber and configured to form a loop with the outlet chamber, the second conduit adapted to transmit a gas flow around the loop and through the outlet chamber. Other embodiments are described and claimed.

### RELATED ART

Integrated circuits may be formed on semiconductor wafers that are formed from materials such as silicon. The semiconductor wafers are processed to form various electronic devices thereon. The wafers are diced into semiconductor chips, which may then be attached to a package substrate using a variety of known methods.

Operation of the integrated circuit generates heat in the device. As the internal circuitry operates at increased clock frequencies and/or higher power levels, the amount of heat generated may rise to levels that are unacceptable unless some of the heat can be removed from the device. Heat is conducted to a surface of the chip (also known as a die), and should be conducted or convected away to maintain the temperature of the integrated circuit below a predetermined level for purposes of maintaining functional integrity of the integrated circuit.

One way to conduct heat from a die is through the use of a heat spreader, which is a body thermally coupled to the die. The heat spreader may be positioned above the die and thermally coupled to the die through a thermal interface material. Materials such as certain solders may be used as a thermal interface material and to couple the heat spreader to the die. A flux is typically applied to at least one of the surfaces to be joined and the surfaces brought into contact. The flux acts to remove the oxide on the solder surfaces to facilitate solder wetting. The thermal interface material may be initially be a solid perform that is positioned between the heat spreader and die. A heating operation at a temperature greater than the melting point of the thermal interface material is carried out, and a connection is made between the die and the heat spreader through the thermal interface material.

### BRIEF DESCRIPTION OF THE DRAWINGS

Embodiments are described by way of example, with reference to the accompanying drawings, which are not drawn to scale, wherein:

FIG. 1 illustrates an indium preform having a native oxide thereon, in accordance with certain embodiments;

FIG. 2 illustrates treating the indium preform of FIG. 1 with fluorine atoms, in accordance with certain embodiments;

FIG. 3 illustrates the formation of oxy-fluoride regions in the native oxide of the indium preform, in accordance with certain embodiments;

FIG. 4 illustrates a treated indium preform positioned between a die and a heat spreader, in accordance with certain embodiments;

FIG. 5 illustrates the formation of a joint with an indium thermal interface material positioned between a die and a heat spreader, in accordance with certain embodiments;

FIG. 6 is a flow chart of certain operations for treating a thermal interface material perform and forming an assembly including a heat spreader bonded to at least one die through the thermal interfaced material, in accordance with certain embodiments;

FIG. 7 illustrates a system which may be used for treating an indium preform, in accordance with certain embodiments; and

FIG. 8 illustrates an electronic system arrangement in which certain embodiments may find application.

### DETAILED DESCRIPTION

Certain embodiments relate to the formation of electronic assemblies. Certain embodiments also relate to a system for performing a processing operation such as a fluorination pre-treatment of an indium thermal interface material.

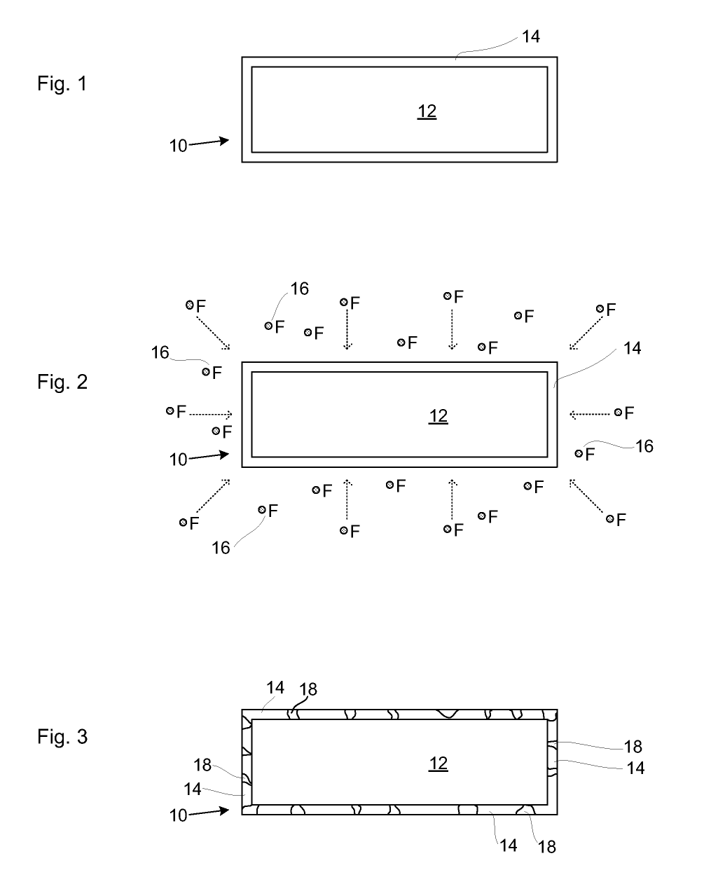

FIG. 1 illustrates an indium body 10, also known as a preform, which may be used as a thermal interface material in accordance with certain embodiments. The indium preform 10 may in certain embodiments includes a core region of indium (In) and a native oxide layer 14 on its surface formed from exposure of the indium to oxygen. The oxide layer 14 protects the core region 12 from further oxidation. The oxide layer 14 is strongly bound to the underlying core region 12. As a result, while carrying out heating of the indium preform 10 during a reflow operation for attaching a heat spreader to a die, during the transition from solidus to liquidus of the indium preform 10, the native oxide layer 14 maintains its solid state, creating a barrier between the liquid indium and the surfaces it needs to bond to. To overcome this problem, a variety of chemical agents may be used as fluxes to remove the native oxide layer and promote bonding. The volatiles present in these fluxes have been identified as a principal source of voids created during the reflow operation and thus the fluxes are responsible for an inefficient transfer of thermal energy from the active areas of the die to the thermal heat spreader.

FIG. 2 illustrates an embodiment in which the indium body 10 is treated prior to placing the indium body between a die and a heat spreader. The treatment includes exposure to highly reactive fluorine (F) species in atomic form 16, in a controlled vacuum atmosphere, such that the fluorine does not react with oxygen or hydrogen in an open atmosphere. Atoms of fluorine 16 are directed towards the indium body 10. A variety of fluorine sources may be used. Due to the toxicity of fluorine, benign fluoride gases, for example, CF₄ and SF₆, may be used to initiate the process. These gases are used to generate the fluorine atoms in the controlled environment, the release being activated by, for example, a microwave induced plasma.

Exposing the indium oxide to the fluorine results in the formation of an oxy-fluoride on the surface. In certain embodiments, the treatment is controlled so that at least part of the native oxide is transformed into an oxy-fluoride and a portion of the native oxide is not transformed. FIG. 3 illustrates an embodiment including an indium preform 10 including the formation of areas of oxy-fluoride 18 within the native oxide layer 14. As seen in FIG. 3, the areas of oxy-fluoride 18 may be surrounded by native oxide 14. The oxy-fluoride 18 has a relatively high melting temperature but is brittle. As a result, when a suitable force is applied, at a temperature lower that its melting point, the oxy-fluoride can be broken (due to its brittleness), and the indium core 12 positioned under the oxy-fluoride 18 can then be exposed.

In certain embodiments, it is believed that a native oxide layer will reform on an oxy-fluoride region within about a week when stored in an air environment. When stored in an inert environment, it is believed that it will take a longer time for a native oxide to form on the oxy-fluoride region. For example, in a nitrogen environment, it is believed that a native oxide layer will form on the oxy-fluoride region within about two weeks. Thus, in such embodiments, the use of the indium preform as a thermal interface material, to couple a heat spreader to a die, should be carried out within these times.

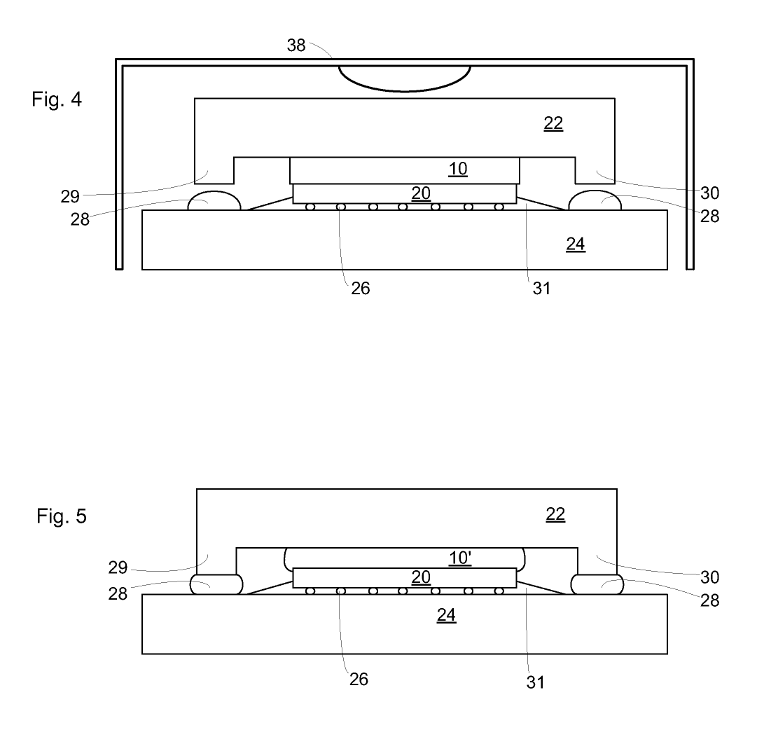

As illustrated in FIG. 4, the indium preform 10 having the oxy-fluoride 18 on the surface may be positioned between a die 20 and a heat spreader 22. The heat spreader 22 may be formed from a variety of materials, including, but not limited to, copper (Cu), and in certain embodiments may include one or more metallization layers formed thereon, such as nickel, which may act as a wetting layer, and gold, which may act to protect the nickel layer from oxidation.

The die 20 may in certain embodiments have a flip-chip configuration with an active die surface facing a package substrate 24 and a back side surface facing the indium preform 10 (the thermal interface material). The back side surface of the die 20 may include a suitable back side metallization (BSM) that may provide oxidation protection and promote the bonding of the die 20 to the indium thermal interface material. In certain embodiments, the back side metallization includes one or more suitable metal layers, for example, titanium (Ti), nickel (Ni) or nickel vanadium (NiV), and gold (Au).

The die 20 may be coupled to the package substrate 24 through, for example, solder bumps 26, and a suitable die underfill material 31, for example, a curable epoxy, may be present. A sealant material 28, which may in certain embodiments be formed from a polymer, may also be formed on the package substrate 24 surface. As illustrated in FIG. 4, the heat spreader 26 may include leg regions 29, 30 that will be positioned on the sealant 32 to form a lid over the die 20 coupled to the substrate 24.

A suitable clip mechanism 38 may be used to hold and apply a suitable force F to the heat spreader 22, package substrate 24, and the indium preform 10 positioned therebetween during the heating operation. In certain embodiments, the clamp or clip mechanism 38 is coupled to a carrier (not shown) which holds the substrate 24. The assembly is then heated to a temperature sufficient to reflow the indium core 12. In certain embodiments, the reflow operation can be conducted either in a standard air atmosphere or a nitrogen controlled atmosphere. The reflow of the indium preform 10 may in certain embodiments be carried out at a temperature that is lower than the melting point of the solder bumps 26.

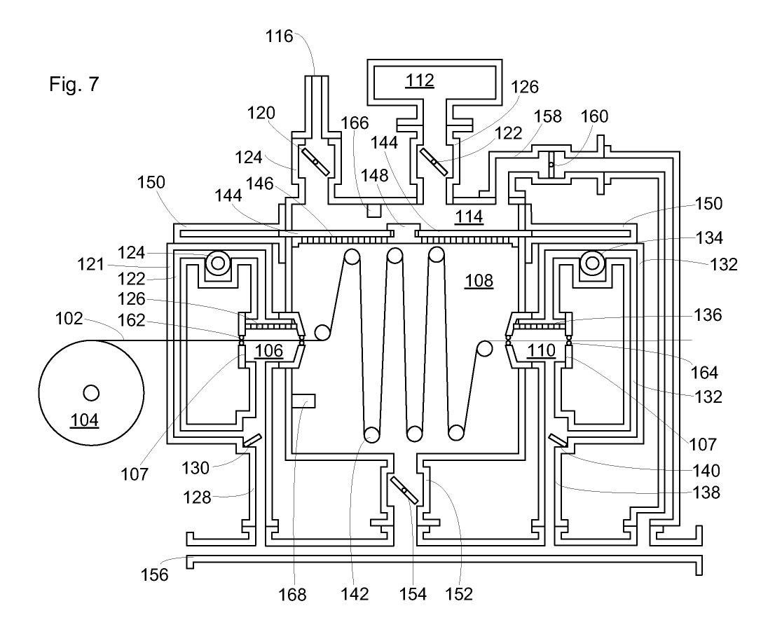

It is believed that the combination of the heat and pressure breaks down the brittle oxy-fluoride regions 18 and permits the indium core 12 of the indium preform 10 to flow and wet the surfaces of the die 20 and heat spreader 22 to form a strong bond therebetween. A flux need not be used, so void formation from flux residue is inhibited. FIG. 5 illustrates an assembly after the heating operation including the heat spreader 22 coupled to the die 24 through the thermal interface material 10′, which includes the reflowed indium preform 10. The joint between the thermal interface material 10′ and the thermal heat spreader 22, and the joint between the thermal interface material 10′ and the die 20, may include material from the indium preform 10 and material from any of the various layer(s) on the heat spreader 22 and die 20, as describe above. Depending on the elements used in the various layers, the finished joint may include a number of layers, including various combinations of the elements used. Some of the combinations may comprise alloys and some may comprise intermetallic compounds. For example, where indium is used in the thermal interface material, and one or more gold layers are used, the joint will in certain embodiments include one or more indium-gold alloys and one or more indium-gold intermetallic compounds. Assemblies including a substrate, die, thermal interface material and thermal spreader formed and joined together as described in embodiments above may find application in a variety of electronic components. Such components may include, but are not limited to, processors, controllers, chipsets, memory, and wireless devices.

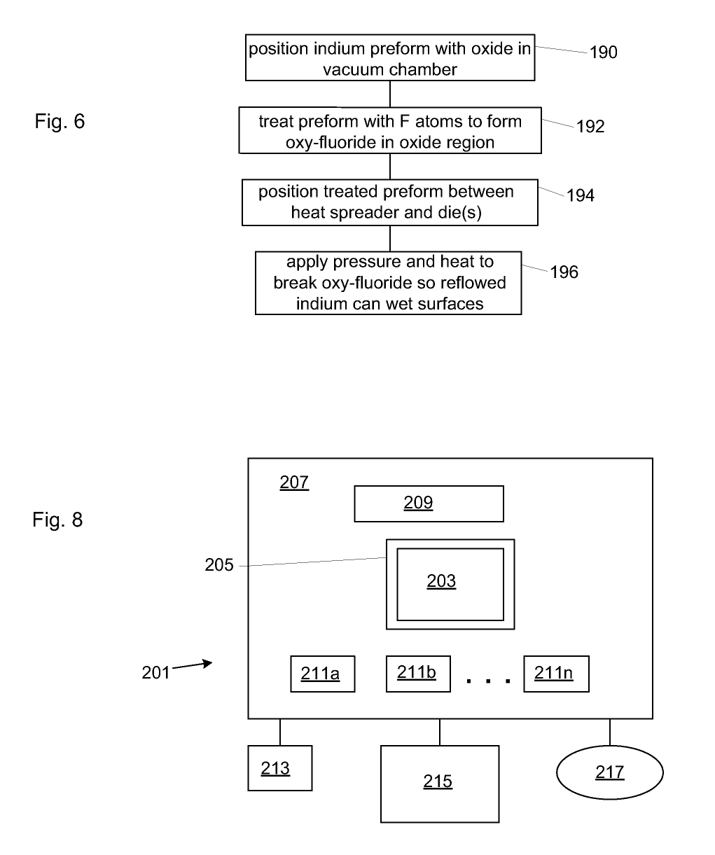

FIG. 6 is a flow chart showing a number of operations in accordance with certain embodiments. Box 190 is positioning in a vacuum chamber an indium preform having an indium core surrounded by a native oxide layer. Box 192 is treating the indium preform by exposing the indium preform to fluorine atoms, to transform at least a portion of the native oxide layer to an oxy-fluoride layer. Box 194 is positioning the treated indium preform between a heat spreader and one or more dies. The heat spreader is adapted to transmit heat away from the one or more dies, with the indium acting as a thermal interface material. Box 196 is applying pressure and heat to the assembly including the indium preform positioned between the heat spreader and die(s), so that the oxy-fluoride breaks down and indium in the core melts and wets the heat spreader and die to form a bond therebetween. A flux is not needed to make the bond between the treated indium preform and the heat spreader.

For large batch processing during the treatment of indium preforms, certain embodiments relate to a system that continuously processes a tape such as a preform tape that includes a plurality of preforms positioned thereon. Such a system is designed to ensure that reactive atoms such as fluorine (F) atoms are kept within a confinement area within the system and delivered into and out of the reaction chamber in a controlled manner. The system may include a plurality of regions, including containment regions and process intensive regions. Certain aspects of such a system will be first discussed, followed by a more detailed explanation referring to specific elements in the system embodiment illustrated in FIG. 7.

To ensure that reactive gas such as fluorine is isolated within the system, the system includes several containment regions adjacent to processing regions. The containment regions include an inlet chamber for introducing the tape into the system prior to the processing chamber and an outlet chamber for removing the tape from the system after treatment in the processing chamber. The inlet chamber and the outlet chamber may each include openings at two ends of the chamber through which a tape can be transferred into and out of, and a conduit that together with the chamber defines a loop through which gas is recirculated. As the gas is recirculated, it will pick up any fluorine atoms that leave the processing chamber and enter the inlet or outlet chambers.

The process intensive regions may include a gas mixing region or chamber where a desired density of reactive atoms is prepared and a processing region or chamber wherein the processing of the tape takes place. For example, when treating indium oxide with fluorine, the reaction is sensitive to the fluorine content and the time of exposure. As a result, depending on factors such as the speed of the tape through the system, the system may need repeated calibration to deliver a desired density of the reactive fluorine to the processing chamber for a desired amount of time, to obtain a desired amount of transformation of indium oxide to an indium oxy-fluoride. As it is difficult to quickly change the concentration of a fluorine precursor gas and diluent gas, the system may include a gas mixing chamber that is separated from the processing chamber by a gate valve that can be quickly opened and closed by varying amounts, to precisely control the amount of gas transferred to the processing chamber where processing of the tape takes place.

As illustrated in the embodiment of FIG. 7, a preform tape 102 from a spool 104 is delivered through an inlet chamber 106 into a processing chamber 108. After treatment, the tape exits the processing chamber 108 through an outlet chamber 110. The inlet chamber 106 and the outlet chamber 110 may also be referred to as load lock chambers. The tape 102 may move along a plurality of inlet chamber rollers 162 as it enters and then exits the inlet chamber 106. The tape may then move along processing chamber rollers 142 as it travels through the processing chamber 108. As the system is designed for the use of a reactive gas, the inlet chamber 106 and the outlet chamber 110 are configured to act as forced air barriers, where a gas flow is recirculated through the chamber using a recirculation fan in a closed loop.

As seen in FIG. 7, the inlet chamber 106 is connected at its top and bottom to a conduit 121 that defines a recirculation path 122 that is a closed-loop path when one or more valves such as valve 130 are closed. A gas acceleration fan 124 may be positioned within the path 122 defined by the conduit 121 to enable an isolation gas to flow through the inlet chamber 106 to be recirculated through conduit 121 and a gas shower head 126 and into the inlet chamber 106. The inlet chamber 106 may have an internal wall 107 that is lined with metallic aluminum (Al) or tin (Sn) foil to act as a fluorine getter. A regulated inlet line may be coupled to the conduit 121 to supply the isolation gas. The isolation gas may be selected from, but is not limited to, air or an inert gas. The isolation gas may be evacuated from the conduit 121 and inlet chamber 106 through an evacuation line 128 in communication with therewith. The evacuation line 128 is regulated by a valve 130, which may be, for example, a butterfly valve.

The outlet chamber 110 may similarly be connected to a conduit 131 that defines a recirculation path 132 that is a closed-loop path when one or more valves such as valve 140 are closed. A gas acceleration fan 134 may be positioned within the path 132 defined by the conduit 131 to enable an isolation gas to flow through the outlet chamber 110 to be recirculated through conduit 131 and a gas shower head 136 and into the outlet chamber 110. The outlet chamber 110 may have an internal wall 109 that is lined with metallic aluminum (Al) or tin (Sn) foil to act as a fluorine getter. A regulated inlet line may be coupled to the conduit 131 to supply the isolation gas. The isolation gas may be selected from, but is not limited to, air or an inert gas. The isolation gas may be evacuated from the conduit 131 and outlet chamber 110 through an evacuation line 138 in communication therewith. The evacuation line 138 is regulated by a valve 140, which may be, for example, a butterfly valve. The evacuation lines 128 and 138 are both in communication with and coupled to system evacuation line 156, which is shown at the bottom of the system in the embodiment illustrated in FIG. 7.

The system as illustrated in the embodiment of FIG. 7 includes a reactive gas source 112 and a mixing gas source 116, which may be spaced apart from one another with separate connections to a gas mixing chamber 114. The reactive gas source 112 may include a chamber adapted to contain reactive ions therein. For example, the reactive gas source 112 may in certain embodiments include a supply of a fluorine containing gas such as SF₆ and/or CF₄ that is subjected to a plasma to generate reactive ions of fluorine. Thus, in certain embodiments, the reactive gas source 112 may comprise a plasma chamber. Other examples of gas sources include, but are not limited to, CHF₃, nitrogen (N) bubbled through an hydrofluoric acid (HF) solution, bottled nitrogen/fluorine mixtures, and bottled argon/fluorine mixtures, pure fluorine, and solid fluorine releasing agents. Depending on the reactive gas source used, the use of a plasma to decompose the source gas into atomic species including fluorine atoms may not be necessary. In certain embodiments, with the tape 102 being an indium preform tape 102, the reactive fluorine atoms will be reacted with at least some of the indium oxide on the perform tape 102 in the processing chamber.

The mixing gas source 116 may include, but is not limited to, a diluent gas such as an inert gas and/or air, depending on the application. The mixing gas and the reactive gas may be combined in a gas mixing chamber 114. A monitor 166 may be present in the gas mixing chamber 114 to monitor the quantity of the reactive gas. The flow of the mixing gas and the reactive gas may be regulated by inlet valves 120 and 122, with inlet valve 120 positioned along a line 124 between the mixing gas source 116 and the gas mixing chamber 114, and with inlet valve 122 positioned along a line 126 between the reactive gas source 112 and the gas mixing chamber 114.

As illustrated in FIG. 7, the gas mixing chamber 114 may be positioned at an upper end of the processing chamber 108. In certain embodiments the gas mixing chamber 114 and the processing chamber 108 are both part of one chamber, with the gas mixing chamber 114 separated from the processing chamber 108 by a gate valve 144 and shower head 146. The gate valve 144 can be opened or closed to regulate the amount of gas flowing from the gas mixing chamber 114, through the shower head 146, and into the processing chamber 108 wherein the tape 102 travels. This arrangement permits a relatively constant mixture of inert gas and reactive gas in the gas mixing chamber 114. The amount of mixed gas that is transferred to the processing chamber 108 can then be regulated by controlling the opening and closing of the gate valve 144. In addition to the monitor 166 in the gas mixing chamber 114, reactive gas monitor 168 for detecting and monitoring the gas may be positioned in the processing chamber 108. Of course, when needed, changes to the relative concentrations of the gases in the mixing gas chamber may be made.

As seen in FIG. 7, when in a closed position, the gate valve 144 extends across the chamber and is seated in frame portion 148 in the middle of the chamber. When opened, the gate valve 144 extends into the frame portions 150 to the sides of the chamber. Gas can be removed from the gas mixing chamber 114 through evacuation line 158 to the system evacuation line 156. A valve such as a butterfly valve 160 may be positioned along the evacuation line 158 to regulate the flow. Gas may exit the processing chamber 108 along an evacuation line 152 to the system evacuation line 156. A valve such as a butterfly valve may be positioned along the evacuation line 152 to regulate the gas flow. The evacuation lines 128, 138, 152, and 158 may all be in communication with and contact the system evacuation line 156 at different locations along the length of the system evacuation line. It should also be noted that by evacuation line it is meant that at least a partial evacuation or removal of gas may be carried out through the line. In addition, conduits and lines as used herein may include suitable pipes, fittings and the like for controlling and directing the flow of gas through the various system components.

After traveling through the outlet chamber 110 on rollers 164, the treated tape 102 may be directed to other machines along a processing line to remove the indium preforms from the tape and perform further processing operations to form electronic assemblies such as, for example, that illustrated in FIG. 5.

Assemblies including a substrate, die, thermal interface material and heat spreader formed and joined together as described in embodiments above may find application in a variety of electronic components. FIG. 8 schematically illustrates one example of an electronic system environment in which aspects of described embodiments may be embodied. Other embodiments need not include all of the features specified in FIG. 8, and may include alternative features not specified in FIG. 8.

The system 201 of FIG. 8 may include at least one central processing unit (CPU) 203. The CPU 203, also referred to as a microprocessor, may be a die which is attached to an integrated circuit package substrate 205, which is then coupled to a printed circuit board 207, which in this embodiment, may be a motherboard. The CPU 203 on the package substrate 205 is an example of an electronic device assembly that may have a structure formed in accordance with embodiments such as described above. A variety of other system components, including, but not limited to memory and other components discussed below, may also include assembly structures formed in accordance with the embodiments described above.

The system 201 further may further include memory 209 and one or more controllers 211a, 211b . . . 211n, which are also disposed on the motherboard 207. The motherboard 207 may be a single layer or multi-layered board which has a plurality of conductive lines that provide communication between the circuits in the package 205 and other components mounted to the board 207. Alternatively, one or more of the CPU 203, memory 209 and controllers 211a, 211b . . . 211n may be disposed on other cards such as daughter cards or expansion cards. The CPU 203, memory 209 and controllers 211a, 211b . . . 211n may each be seated in individual sockets or may be connected directly to a printed circuit board. A display 215 may also be included.

Any suitable operating system and various applications execute on the CPU 203 and reside in the memory 209. The content residing in memory 209 may be cached in accordance with known caching techniques. Programs and data in memory 209 may be swapped into storage 213 as part of memory management operations. The system 201 may comprise any suitable computing device, including, but not limited to, a mainframe, server, personal computer, workstation, laptop, handheld computer, handheld gaming device, handheld entertainment device (for example, MP3 (moving picture experts group layer-3 audio) player), PDA (personal digital assistant) telephony device (wireless or wired), network appliance, virtualization device, storage controller, network controller, router, etc.

The controllers 211a, 211b . . . 211n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 213 in accordance with a storage protocol layer. The storage protocol of the layer may be any of a number of known storage protocols. Data being written to or read from the storage 213 may be cached in accordance with known caching techniques. A network controller can include one or more protocol layers to send and receive network packets to and from remote devices over a network 217. The network 217 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. A system adapted to receive and process a tape, comprising:
a gas mixing chamber adapted to receive a plurality of gases;
a processing chamber adapted to receive gas from the gas mixing chamber and adapted to receive a tape to be processed using the gas;
a gate valve positioned between the gas mixing chamber and the processing chamber;
an inlet chamber adapted to transmit an unprocessed tape into the processing chamber;
an outlet chamber adapted to receive a processed tape from the processing chamber;
a first conduit in communication with the inlet chamber and configured to form a loop with the inlet chamber, the first conduit adapted to transmit a gas flow around the loop and through the inlet chamber; and
a second conduit in communication with the outlet chamber and configured to form a loop with the outlet chamber, the second conduit adapted to transmit a gas flow around the loop and through the outlet chamber.

2. The system of claim 1, further comprising:
an inlet chamber evacuation line in communication with the first conduit;
an inlet chamber evacuation line valve adapted to open and close the flow of gas through the inlet chamber evacuation line;
an processing chamber evacuation line in communication with the processing chamber;
a processing chamber evacuation line valve adapted to open and close the processing chamber evacuation line;
an outlet chamber evacuation line in communication with the second conduit;
an outlet chamber evacuation line valve adapted to open and close the outlet chamber evacuation line; and
a system evacuation line in communication with the inlet chamber evacuation line, the processing chamber evacuation line, and the outlet chamber evacuation line.

3. The system of claim 1, further comprising a gas mixing chamber evacuation line in communication with the gas mixing chamber; and
a gas mixing chamber evacuation line valve adapted to open and close the gas mixing chamber evacuation line;
wherein the gas mixing chamber evacuation line is also in communication with the system evacuation line.

4. The system of claim 1, further comprising a first gas acceleration fan positioned to accelerate gas through the first conduit; and a second gas acceleration fan positioned to accelerate gas through the second conduit.

5. The system of claim 1, further comprising a plasma chamber in communication with the gas mixing chamber.

6. The system of claim 5, further comprising a supply of gas comprising fluorine in communication with the plasma chamber.

7. The system of claim 5, further comprising a supply of a diluent gas in communication with the gas mixing chamber.

8. The system of claim 1, further comprising a tape comprising a plurality of indium preforms thereon, the indium preforms including indium oxide thereon, the tape being positioned to extend into the inlet chamber, the processing chamber, and the outlet chamber.

9. The system of claim 8, wherein the processing chamber includes a gas comprising fluorine atoms therein.

10. The system of claim 1, further comprising a source of a reactive gas in communication with the gas mixing chamber at a first location, and a source of a diluent gas in communication with the gas mixing chamber at a second location spaced a distance away from the first location.

11. The system of claim 1, further comprising a first gas shower head positioned in the inlet chamber, a second gas shower head positioned in the outlet chamber, and a third gas shower head positioned in the processing chamber.

12. The system of claim 1, further comprising a first reactive gas monitor positioned in the gas mixing chamber, and a second reactive gas monitor positioned in the processing chamber.

13. A system adapted to receive and process a tape, comprising:
a gas mixing chamber adapted to receive a plurality of gases;
a processing chamber adapted to receive gas from the gas mixing chamber and adapted to receive a tape to be processed using the gas;
a gate valve positioned between the gas mixing chamber and the processing chamber;
an inlet chamber adapted to transmit an unprocessed tape into the processing chamber;
an outlet chamber adapted to receive a processed tape from the processing chamber;
a first conduit in communication with the inlet chamber and configured to form a first loop with the inlet chamber;
a first fan positioned to recirculate a gas flow through the first loop including the first conduit and the inlet chamber;
a second conduit in communication with the outlet chamber and configured to form a second loop with the outlet chamber;
a second fan positioned to recirculate a gas flow through the second loop including the second conduit and the outlet chamber;
a first evacuation line in communication with the first conduit;
a first valve adapted to open and close the first conduit line;
a second evacuation line in communication with the second conduit;
a second valve adapted to open and close the second conduit line;
a third evacuation line in communication with the processing chamber;
a third valve adapted to open and close the third evacuation line;
a fourth evacuation line in communication with the gas mixing chamber;
a fourth valve adapted to open and close the fourth evacuation line; and
an output evacuation line having a length, the output evacuation line in communication with the first evacuation line at a first position along the length, the second evacuation line at a second position along the length, the third evacuation line at a third position along the length, and the fourth evacuation line at a fourth position along the length.

14. The system of claim 13, further comprising a reactive gas source adapted to supply a reactive gas to the gas mixing chamber.

15. The system of claim 14, further comprising a diluent gas source adapted to supply a diluent gas to the gas mixing chamber.

16. The system of claim 13, wherein the reactive gas source includes a plasma chamber adapted to ionize a gas and direct atoms of the ionized gas to the gas mixing chamber.

17. A method for processing a tape including a plurality of indium preforms, comprising:
providing a tape including a plurality of indium preforms positioned thereon, the indium preforms each including a body comprising indium, the body including an indium oxide surface layer; and
delivering the tape to an inlet chamber;
passing a recirculating gas flow on the tape in the inlet chamber;
delivering the tape from the inlet chamber to a processing chamber, the processing chamber including fluorine atoms therein;
reacting a plurality of the fluorine atoms in the processing chamber with the indium oxide surface layer on the preforms, to form indium oxy-fluoride on the preforms;
delivering the tape to an outlet chamber, wherein the tape in the outlet chamber include indium preforms having both indium oxy-fluoride and indium oxide surface regions; and
passing a recirculating gas flow on the tape in the outlet chamber.

18. The method of claim 17, wherein the reacting a plurality of the fluorine atoms in the processing chamber with the indium oxide surface layer on the preforms, to form indium oxy-fluoride on the preforms, is controlled so that the preforms include a surface having indium oxide and indium oxy-fluoride regions.

19. The method of claim 17, wherein the fluorine atoms in the processing chamber are obtained by processing a gas comprising fluorine in a plasma chamber to obtain atoms of fluorine, and delivering the atoms of fluorine to the processing chamber.

20. The method of claim 19, wherein the fluorine atoms are delivered from the plasma chamber to a gas mixing chamber and mixed with a diluent gas in the gas mixing chamber prior to being delivered to the processing chamber.
